(19) United States
(12) Patent Application Publication
(10) Pub. No.: US 2011/0031116 A1
(43) Pub. Date: Feb. 10, 2011

(54) MAGNETRON SPUTTERING TARGET ASSEMBLY AND COATING APPARATUS HAVING SAME

(75) Inventor: SHAO-KAI PEI, Tu-Cheng (TW)

Correspondence Address: Altis Law Group, Inc.;ATTN: Steven Reiss, 288 SOUTH MAYO AVENUE, CITY OF INDUSTRY, CA, 91789, US

(73) Assignee: HON HAI PRECISION INDUSTRY CO., LTD., Tu-Cheng (TW)

(21) Appl. No.: 12/758,034

(22) Filed: Apr. 12, 2010

(30) Foreign Application Priority Data
Aug. 7, 2009 (CN) 200910305378.1

(51) Int. Cl. C23C 14/35

(52) U.S. Cl. 204/298.09; 204/298.12; 204/298.13

(57) ABSTRACT

A coating apparatus includes a shielding casing defining a chamber, a substrate holder received in the chamber and a target assembly located inside the shielding casing. The substrate holder is configured to hold a substrate. The target assembly faces the substrate. The target assembly includes a target frame, two opposite target electrodes, a number of magnetrons and a transport unit. The target base includes two opposite end surfaces and a number of side surfaces interconnecting the end surfaces. The two opposite target electrodes are fixed on the two opposite side surfaces. The magnetrons are received in the receiving cavity and disposed between the target electrodes. The transport unit is configured to carry the magnetrons to circulate therearound.

### BACKGROUND

1. Technical Field

This present disclosure relates to coating apparatuses, and particularly, to a coating apparatus with a magnetron sputtering target assembly.

2. Description of Related Art

Magnetron sputtering is method used to form a thin film on a substrate during manufacturing semiconductor devices or other electronic devices.

In a conventional sputtering apparatus, a deposition substrate and a target, which together are used to form a thin film, are disposed opposite to each other within a vacuum reaction vessel or a vacuum chamber. A discharge gas, such as argon gas, is then injected into the vacuum reaction vessel or the vacuum chamber in a high vacuum state. Electrical discharge of the discharge gas is started by applying a negative voltage to the target. Due to the discharge, gas molecules are ionized then accelerated by the negative voltage to collide with the target. The surface of the target emits atoms that are sputtered in various directions, and some of the atoms are deposited on the substrate, thereby forming a thin film.

A number of magnetrons configured to provide a magnetic field for limiting the movement of the ions are fixed on the rear surface of the target. It is difficult to achieve uniform performances with the magnetrons, resulting in a non-uniform thin film.

Therefore, it is desirable to provide a magnetron sputtering target assembly and a coating apparatus using same, which can overcome or at least alleviate the above-mentioned limitations.

### BRIEF DESCRIPTION OF THE DRAWINGS

FIG. 1 is a schematic cross-section view of a coating apparatus, according to an exemplary embodiment.

FIG. 2 is an isometric view of a magnetron sputtering target assembly of the coating apparatus of FIG. 1.

FIG. 3 is a partial, cross-sectional view taken along line III-III of the target assembly of FIG. 2.

FIG. 4 is another partial, cross-sectional view taken along line IV-IV of the target assembly of FIG. 2.

### DETAILED DESCRIPTION

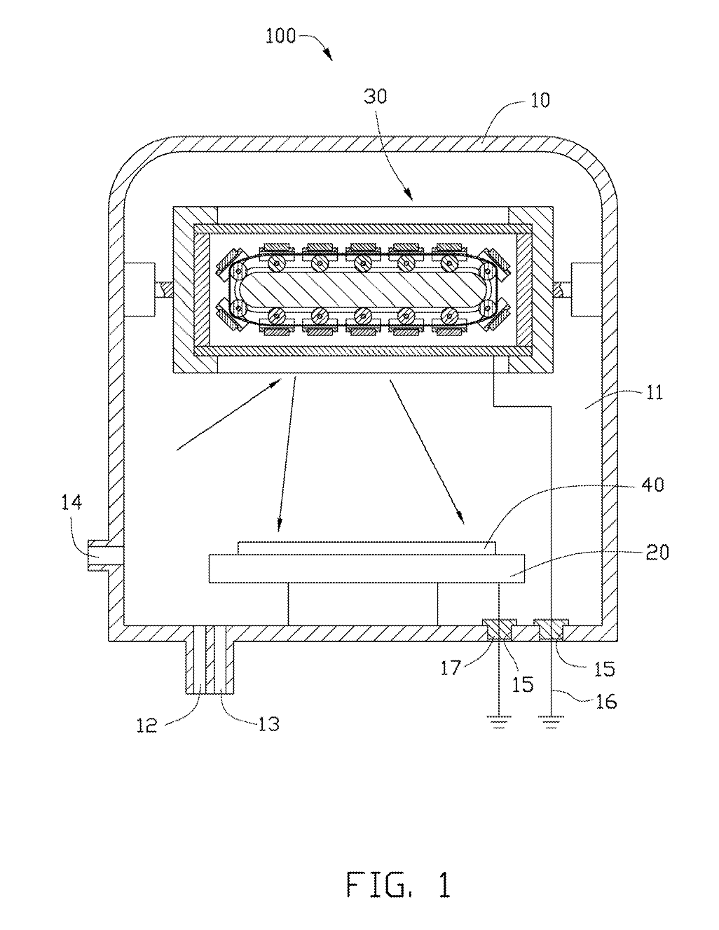

Referring to FIG. 1, a coating apparatus 100, according to an exemplary embodiment, includes a shielding casing 10, a substrate holder 20 and a magnetron sputtering target assembly 30. The holder 20 and the target assembly 30 are located inside the casing 10. The holder 20 is located opposite to the target assembly 30 and configured to hold a substrate 40 thereon for coating.

The casing 10 is generally cubic and defines a chamber 11. The casing 10 defines a discharge gas inlet 12, a discharge gas outlet 13, a vacuumizing hole 14 and at least one grounding hole 15 communicating with the chamber 11 and disposed on the bottom wall thereof. In the present disclosure, the at least one grounding hole 15 includes two grounding holes 15. The target assembly 30 and the holder 20 each include an electrical wire 16 run through the grounded holes 15, configured for connecting the target assembly 30 and the substrate 40 to ground. It is noteworthy that the grounding holes 15 may be sealed with an elastic element 17.

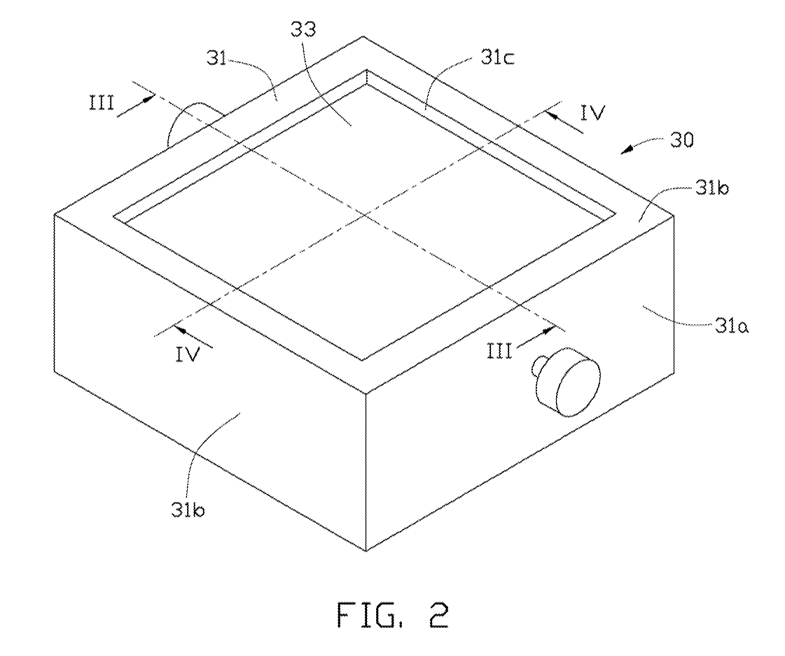

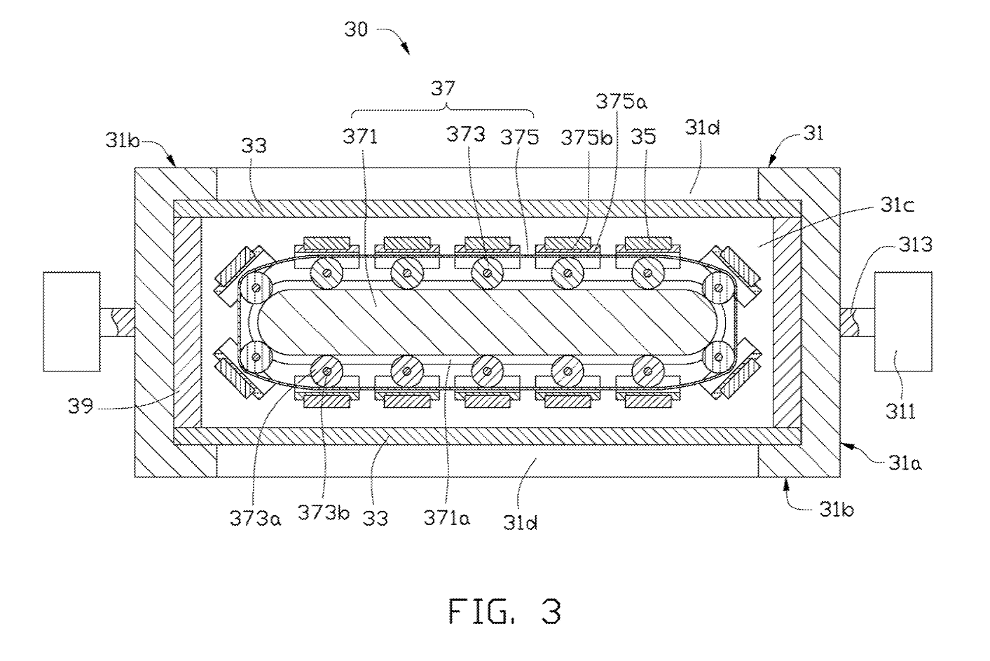

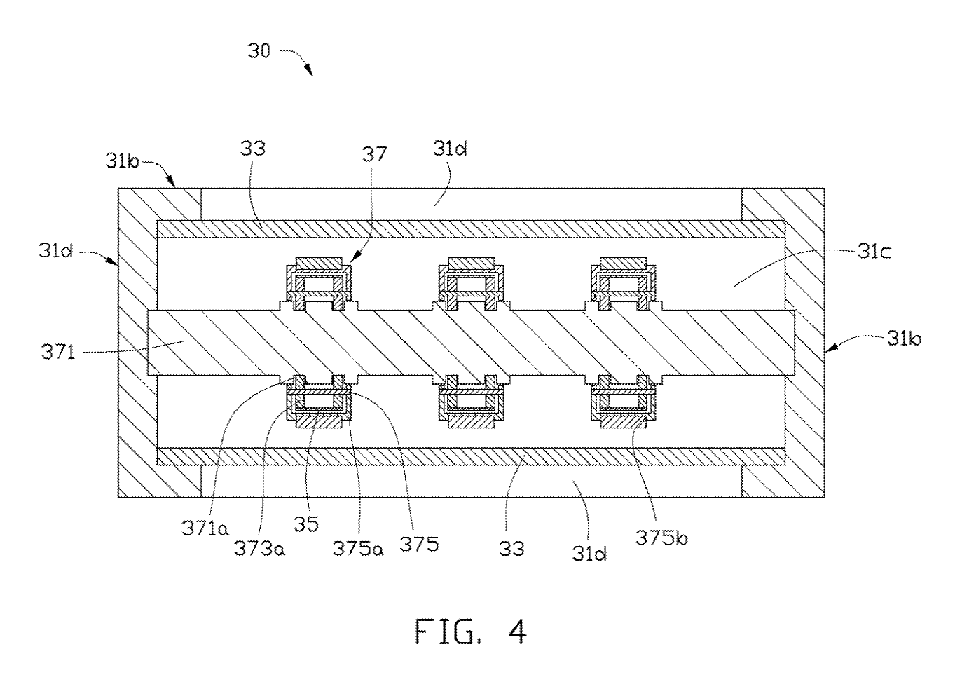

Referring to FIGS. 2 to 4, the target assembly 30 includes a target frame 31, two opposite target electrodes 33 received in and fixed to the target frame 31, a number of magnetrons 35 received in the target frame 31 and disposed between the target electrodes 33, and a transport unit 37 configured to circularly move the magnetrons 35. In addition, a majority of the magnetrons 35 are located on two parallel common planes which are parallel with the target electrodes 33.

The target frame 31 includes two opposite end surfaces 31a and four side surfaces 31b interconnecting the end surfaces 31a. A receiving cavity 31c is surrounded by the end surfaces 31a and the side surfaces 31b. Two opposite side surfaces 31b each define an opening 31d communicating with the receiving cavity 31c. Two drivers 311 disposed outside the casing 10 are rotatably connected to the two end surfaces 31a by two shafts 313 respectively. The two drivers 311 are configured for rotating the target frame 31. In the present disclosure, the driver 311 is a motor. The target frame 31 further includes a cooling structure 39 located in the receiving cavity 31c and positioned between the target electrodes 33 and the end surfaces 31a, configured to cool the target electrode 33. In the present disclosure, the cooling structure 39 includes a number of heat pipes arranged on the end surfaces 31a.

The target electrodes 33 are made of at least one kind of material to be deposited on the substrate 40. In the present disclosure, the two target electrodes 33 are made of two different kinds of materials with one target electrode 33 being made of copper and the other electrode 33 being made of nickel. It is noted that the electrodes 33 can be made of any material which is expected for coating. Each target electrode 33 is rectangular. Each target electrode 33 is longer than the opening 31d and can be seen through the opening 31d.

The transport unit 37 includes a base plate 371, a number of rollers 373 surrounding the base plate 371, and at least one transmission belt 375.

The base plate 371 is shaped corresponding to but slightly smaller than the opening 31d. Two opposite ends of the base plate 371 are fixed to the end surfaces 31a of the target frame 31, thus the base plate 371 may be parallel with and located between the target electrodes 33. In the present disclosure, the base plate 371 is welded to the target frame 31. Furthermore, the base plate 371 defines a number of parallel annular slots 371a on the outer surface thereof.

Each roller 373 includes two wheels 373a, a shaft 373b interconnected between the two wheels 373a, and a motor (not shown) for driving the shaft 373b to rotate, thereby driving the two wheels 373b to rotate together. In the present disclosure, the two wheels 373a of each roller 373 are received in two adjacent annular slots 371a respectively.

The transmission belt 375 tightly attaches to and wraps around all of the shafts 373b around the base plate 371, for rotating the rollers 373 to convey the magnetrons 35. The friction force between the shaft 373b and the transmission belt 375 is sufficient to drive the transmission belt 375 to move together with the shaft 373b. A number of seats are arranged on the transmission belt 375. Each seat 375a defines a positioning groove 375b configured for positioning one magnetron 35 thereon, thereby the magnetrons 35 can move together with the transmission belt 375.

In operation, the substrates 40 are placed on the substrate holder 20. Then the casing 10 is vacuumized via the vacuumizing hole 14. When the motor of the transport unit 37 starts rotating and the transmission belt 375 drives the magnetrons 35 to move around the base plate 371, a uniform magnetic field is produced around the target electrodes 33. Then, discharge gas is injected into the casing 10 through the discharge gas inlet 12 and discharges to apply a negative voltage to the target electrodes 33. Due to the discharge, the gas molecules in the chamber 11 are ionized, and then accelerated by the negative voltage to collide with the target electrodes 33. The surfaces of the target electrodes 33 emit atoms that are deposited on the substrate 40 according to the direction of the magnetic field generated by the moving magnetrons 35. Since the magnetic field in the casing 10 is kept uniform due to the movement of the magnetrons 35, the emission of the atoms also can be kept uniform, thus forming a uniform thin film on the substrate 40. Furthermore, when the coating process is finished and one of the target electrodes 33 is used up, the driver 311 restarts and the other target electrode 33 can be driven to rotate back to face the substrate 40 by the driver 311, for coating another layer on the substrate 40. It is convenient for coating another layer without re-vacuumizing the chamber 11.

While various exemplary and preferred embodiments have been described, it is to be understood that the disclosure is not limited thereto. To the contrary, various modifications and similar arrangements (as would be apparent to those skilled in the art), are also covered. Therefore, the scope of the appended claims should be accorded the broadest interpretation so as to encompass all such modifications and similar arrangements.

What is claimed is:

1. A coating apparatus comprising:
a shielding casing defining a chamber therein;
a holder received in the chamber and configured to hold a substrate; and
a target assembly located inside the shielding casing and facing the substrate holder, the target assembly comprising:
a target frame comprising two opposite end surfaces and a plurality of side surfaces interconnecting the end surfaces, the end surfaces and the side surfaces cooperatively defining a receiving cavity therein;
two opposite target electrodes received in the receiving cavity and fixed on the side surfaces of the target base;
a plurality of magnetrons received in the receiving cavity and disposed between the target electrodes; and
a transport unit configured to carry the magnetrons to circulate therearound.

2. The coating apparatus of claim 1, wherein the casing defines a discharge gas inlet, a discharge gas outlet, a vacuumizing hole and a grounding hole communicating with the chamber.

3. The coating apparatus of claim 2, wherein the target and the holder are grounded.

4. The coating apparatus of claim 1, wherein each side surface defines an opening communicating with the receiving cavity, the target electrode is rectangular and is longer than the opening, the target electrodes are accessible through the opening.

5. The coating apparatus of claim 1, wherein two drivers disposed outside the shielding casing are rotatably connected to the two end surfaces configured for rotating the target frame.

6. The coating apparatus of claim 1, wherein the target frame further comprises a cooling structure positioned between the target electrodes.

7. The coating apparatus of claim 1, wherein one of the two target electrodes is made of copper, and the other is made of nickel.

8. The coating apparatus of claim 1, wherein the transport unit comprises a base plate, a plurality of rollers surrounding the base plate and a transmission belt, two opposite ends of the base plate are fixed to the end surfaces of the target frame, each roller is attached to the base plate and rotatable relative to the base plate, and the transmission belt surrounds the rollers and is configured for conveying the magnetrons.

9. The coating apparatus of claim 8, wherein the base plate defines two parallel annular slots therearound, each roller comprises two wheels, a shaft interconnected between the two wheels, and a motor for rotating the shaft, the two wheels of each roller are received in two annular slots respectively, the transmission belt tightly wraps around all of the shafts.

10. The coating apparatus of claim 9, wherein a plurality of seats are arranged on the transmission belt, and each seat defines a positioning groove positioning one magnetron thereon.

11. The coating apparatus of claim 9, wherein the friction force between the shaft and the transmission belt is sufficient to drive the transmission belt to move together with the rotation of the shaft.

12. A magnetron sputtering target assembly comprising:
a target frame comprising two opposite end surfaces and a plurality of side surfaces interconnecting the end surfaces, the end surfaces and the side surfaces cooperatively defining a receiving cavity therein;
two opposite target electrodes received in the receiving cavity and fixed on the side surfaces of the target base;
a plurality of magnetrons received in the receiving cavity and disposed between the target electrodes; and
a transport unit configured to carry the magnetrons to circulate therearound.

13. The magnetron sputtering target assembly of claim 12, wherein the target frame further comprises a cooling structure positioned between the target electrodes.

14. The magnetron sputtering target assembly of claim 12, wherein the two target electrodes are made of two different kinds of materials.

15. The magnetron sputtering target assembly of claim 12, wherein the transport unit comprises a base plate, a plurality of rollers surrounding the base plate and a transmission belt, two opposite ends of the base plate are fixed to the end surfaces of the target frame, each roller is attached to the base plate and rotatable relative to the base plate, and the transmission belt surrounds the rollers and is configured for conveying the magnetrons.

16. The magnetron sputtering target assembly of claim 15, wherein the base plate defines two parallel annular slots therearound, each roller comprises two wheels, a shaft interconnected between the two wheels, and a motor for rotating the shaft, the two wheels of each roller are received in two annular slots respectively, the transmission belt tightly wraps around all of the shafts.

17. The magnetron sputtering target assembly of claim 16, wherein a plurality of seats are arranged on the transmission belt, and each seat defines a positioning groove positioning one magnetron thereon.

18. The magnetron sputtering target assembly of claim 16, wherein the friction force between the shaft and the transmission belt is sufficient to drive the transmission belt to move together with the rotation of the shaft.
